(19) United States
(12) Patent Application Publication
(10) Pub. No.: US 2014/0050335 A1
(43) Pub. Date: Feb. 20, 2014

(54) Very High Fidelity Audio Amplifier

(71) Applicant: Pirre-Emmanuel Calmel, Versailles (FR)

(72) Inventors: Mathias Moronvalle, Vauhallan (FR); Pirre-Emmanuel Calmel, Versailles (FR)

(21) Appl. No.: 13/582,327

(22) PCT Filed: Mar. 16, 2010
(86) PCT No.: PCT/FR2010/050469

§ 371 Date: Apr. 15, 2013

(30) Foreign Application Priority Data
Mar. 2, 2010 (FR) 1051516

(51) Int. Cl. H03F 3/185; H03F 1/30

(52) U.S. Cl. CPC H03F 3/185; H03F 1/301
USPC 381/120

(57) ABSTRACT

This high fidelity audio amplifier with very low distortion and high efficiency (10) includes:
an input (12) for an audio signal to be amplified and an output (14) for feeding a load (16) with the amplified audio signal;
a reference voltage generator (18) having very high linearity and low output impedance, capable of receiving as an input the musical signal to be amplified;
a power voltage generator (20), the output of which is connected to the output of the reference voltage generator (18), through a coupling impedance (22), the modulus of which is at least ten times lower than the modulus of the impedance of the load (16) capable of being fed by the output (14) of the amplifier; and
means (28A, 28B, 30, 32) for inputting at the input of the power voltage generator (20), a representative signal of the current provided at the output by the reference voltage generator (18).

The means (28A, 28B, 30, 32) for inputting at the input of the power voltage generator (20), a representative signal of the current provided at the output by the reference voltage generator (18) are capable of ensuring linear control of the power voltage generator (20).

The present invention relates to a very high fidelity audio amplifier having very low distortion and high efficiency of the type including:
an input for an audio signal to be amplified and an output for feeding a load with the amplified audio signal;
a reference voltage generator with very high linearity and low output impedance, suitable for receiving as an input the musical signal to be amplified;
a power voltage generator, the output of which is connected to the output of the reference voltage generator through a coupling impedance, the modulus of which is at least 10 times lower than the modulus of the impedance of the load suitable for being fed by the output of the amplifier; and
means for inputting, at the input of the power voltage generator a representative signal of the current supplied at the output by the reference voltage generator.

Document U.S. Pat. No. 6,937,095 describes an amplifier including two voltage generators coupled at the output. Both of these generators are voltage generators in the sense that they have a very low output impedance.

In this amplifier, of the state of the art, the reference voltage generator behaves as a follower while the power voltage generator provides, through an impedance, the output current required for feeding the load. The reference voltage generator is built so as to have very high linearity and low output impedance so as to obtain low distortions at the output of the amplifier.

The current consumed by the reference voltage generator is measured and its value is used for ensuring the control of the amplification units of the power voltage generator. Thus, the essential part of the electric power is provided by the power voltage generator.

However, even if it is not much use, the reference voltage generator with very high linearity is put to work in order to contribute to providing the output signal, which is detrimental to the accuracy of the amplified output signal.

The object of the invention is to propose an amplifier having further improved output performances, notably as regards the distortion level.

For this purpose, the object of the invention is an amplifier of the aforementioned type, characterizing that the means for inputting at the input of the power voltage generator, a representative signal of the provided current at the output by the reference voltage generator are capable of ensuring a linear control of the power voltage generator.

According to particular embodiments, the amplifier includes one or more of the following features:
the means for inputting at the input of the power voltage generator, a representative signal of the current provided at the output by the reference voltage generator include a proportional integral derivative controller (PID);
the amplifier includes means for inputting at the input of the power voltage generator, a representative signal of the musical signal to be amplified, in addition to the representative signal of the current provided at the output by the reference voltage generator;
the output of the reference voltage generator is directly connected to the output feeding the load without interposition of an impedance;
the power voltage generator is an amplification stage of Class D;
the power voltage generator is driven in pulse width or sigma/delta modulation, and the coupling impedance is an inductance, a resistance or the combination of both;
the power voltage generator is an analog amplification stage of class A or AB, and the coupling impedance is a resistance, an inductance or the combination of both;
said means for inputting at the input of the power voltage generator a representative signal of the current provided at the output by the reference voltage generator include means for measuring the instantaneous intensity consumed by the reference voltage generator;
said means for inputting at the input of the power voltage generator a representative signal of the current provided at the output by the reference voltage generator include means for measuring the current provided by the reference voltage generator, only positioned upstream from the output for feeding the load and the output of the reference voltage generator is directly connected to the coupling point without interposition of any resistive element between them; and
the output impedance of the reference voltage generator is less than 0.2 Ohms.

The invention will be better understood upon reading the following description, only given as an example and made with reference to the single figure wherein the electric diagram of a high fidelity audio amplifier having low distortion and very high efficiency according to the invention is illustrated.

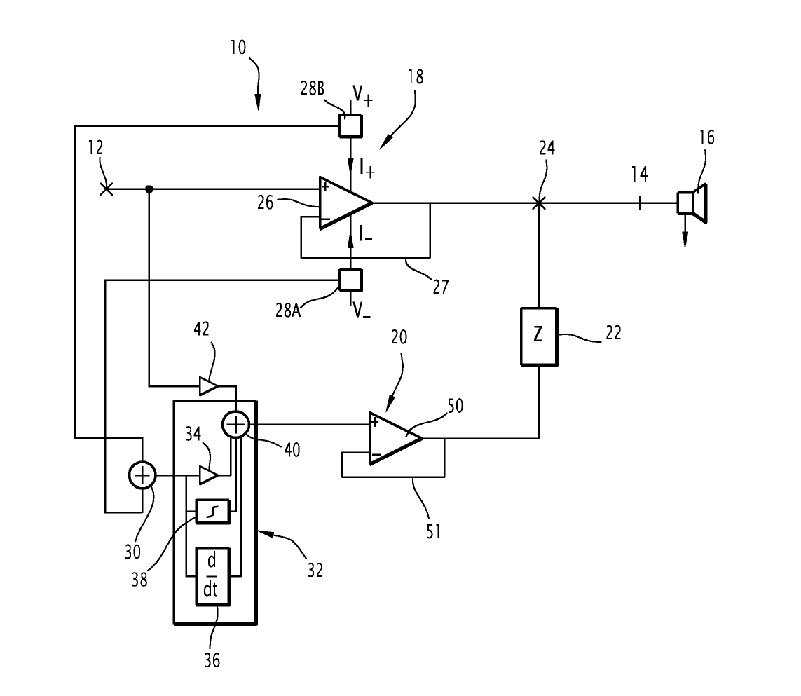

The audio amplifier 10 illustrated in FIG. 1 includes an input 12 capable of receiving an analog audio signal to be amplified and an output 14 for providing the amplified signal, to which is connected a load formed with a loudspeaker 16. The loudspeaker 16 is directly connected, without any other resistive element, between the output 14 of the amplifier and the ground.

The input 12 of the amplifier is capable of receiving a control voltage, the reference of which is the ground.

The amplifier 10 includes a reference voltage generator 18 having very high linearity and low output impedance and a power voltage generator 20. The outputs of both generators are coupled with each other at the output 14 through a coupling impedance 22.

The input of the reference voltage generator 18 is directly connected, without interposition of any impedance to the input 12 of the amplifier while the output of the reference voltage amplifier 18 is directly connected to the output 14 without interposition of any resistive, capacitive or inductive element.

The outputs of the voltage generators 18 and 20 are connected in a coupling point 24, the coupling impedance 22 being positioned between the output of the power voltage generator 20 and the coupling point 24.

The reference voltage generator 18 includes a voltage amplification stage 26 schematized by a differential amplifier, the non-inverting input is directly connected to the input 12 and the inverting input of which is connected to the feedback loop 27 directly connected to the output of the differential amplifier 26. Preferably, the voltage amplification stage is formed for example with an operational amplifier mounted as a voltage follower.

The reference voltage generator 18 is an amplifier of class A having very linearity and low output impedance. Preferably, the output impedance of the reference voltage generator is less than 0.2 Ohms.

The differential amplifier 26 is powered by two DC voltages V, and V_{—} and consumes a current noted as I₁ and I₂ respectively on each of these supply inputs.

Means for measuring the consumed current 28A, 28B are provided on each of the supply inputs of the differential amplifier 26.

These means are for example formed with current detectors as described in document U.S. Pat. No. 6,937,095. They are capable of providing a representative piece of information on the current provided at the output by the reference voltage generator, the current provided by the generator 18 being directly linked to the current which it consumes.

The outputs of the current sensors 28A, 8B are connected to a summing circuit 30 forming the input of a linear controller of the PID type 32 including a linear amplification stage 34, a differentiation stage 36 and an integration stage 38, each mounted in parallel and receiving as an input a representative value of the sum of the currents consumed by the reference voltage generator 18. The outputs of 34, 36 and 38 are connected to an adder 40. Thus, the PID controller 32 is capable of providing at the output a representative signal of the current provided at the output by the reference generator 18.

Further, the summing circuit 40 is connected through another input to the input 12, via a linear amplification stage 42 for receiving the musical signal to be amplified.

The power voltage generator 20 is formed in the relevant example with a differential amplifier 50 mounted as a follower, and the inverting input of which is directly connected to the output through a feedback loop 51 while the non-inverting input is connected to the output of the summing circuit 40.

Thus, the power voltage generator 20 is capable of receiving as an input a combination of the audio signal to be amplified from the input 12 and a representative value of the current consumed by the reference voltage generator.

According to a first embodiment, the differential amplifier 50 consists of an amplifier of class D, i.e. an amplifier of the <<push/pull>> type including along its amplifier branch two <<MOSFET>> transistors mounted in opposite series, both of these transistors being driven according to a pulse width modulation law. In this case, the impedance 22 consists of an inductance, a resistance or the combination of both. Alternatively, both transistors are driven according to a sigma/delta law.

According to another embodiment, the power voltage generator 20 consists of an amplifier class A or of class AB. In this case, the coupling impedance 22 consists of an inductance, a resistance or the combination of both.

Advantageously, the coupling impedance 22, whether this is a coil or a resistor has a modulus lower than ten times the modulus of the load, i.e. of the loudspeaker 16 in the useful frequency range.

Thus, for example for a loudspeaker, the resistance of which is 4 Ohms, the resistor 22 used in the case of an amplifier of class AB for forming the power voltage generator 20 is less than 0.4 Ohms

Also, in the case of an amplifier class D forming the power voltage generator 20 for feeding a loudspeaker, the inductance of which is 1 mH and the resistance is 4 Ohms, the inductance of the coil forming the coupling impedance is less than 100 pH.

According to another embodiment, the representative value of the current provided by the reference voltage generator introduced into the PID controller 32 is given by the difference of the potentials measured on the terminals of the impedance 22 and of an additional resistor positioned between the coupling point 24 and the output 14 according to the circuit described in document FR 2 873 872.

It is conceivable that with such an arrangement, the taking into account of the input signal of the amplifier directly on the input of the power voltage generator 12, in addition to the representative signal of the current provided by the reference voltage generator further alleviates the activation of the reference voltage generator thereby improving the linearity of the class A amplifier acting as a reference voltage generator and reducing distortion by as much.

By resorting to linear control, it is possible to avoid saturation conditions of the sensors for measuring currents 28A, 28B and of the amplifier 20 at the limits of the linearity range of these components.

1. An audio amplifier including:
an input for an audio signal to be amplified and an output for feeding a load with the amplified audio signal;
a reference voltage generator having very high linearity and low output impedance, capable of receiving as an input the audio signal to be amplified;
a power voltage generator, the output of which is connected to the output of the reference voltage generator through a coupling impedance, the modulus of which is at least 10 times lower than the modulus of the impedance of the load capable of being fed by the output of the amplifier; and
means for inputting at the input of the power voltage generator, a representative signal of the current provided at the output by the reference voltage generator, which means for inputting at the input of the power voltage generator, a representative signal of the current provided at the output by the reference voltage generator, are capable of ensuring linear control of the power voltage generator, characterized in that the means for inputting at the input of the power voltage generator, a representative signal of the current provided at the output by the reference voltage generator include a proportional-integral-derivative controller (PID).

2. The amplifier according to claim 1, characterized in that it includes means for inputting at the input of the power voltage generator, a representative signal of the audio signal to be amplified, in addition to the representative signal of the current provided at the output by the reference voltage generator.

3. The amplifier according to claim 1, characterized in that the output of the reference voltage generator is directly connected to the output for feeding the load without interposition of any impedance.

4. The amplifier according to claim 1, characterized in that the power voltage generator is an amplification stage of class D.

5. The amplifier according to claim 4, characterized in that the parallel voltage generator is driven in pulse width or sigma/delta modulation and in that the coupling impedance is an inductance, a resistance or the combination of both.

6. The amplifier according to claim 1, characterized in that the power voltage generator is an analog amplification stage of Class A or AB and in that the coupling impedance is a resistance, an inductance or a combination of both.

7. The amplifier according to claim 1, characterized in that said means for inputting at the input of the power voltage generator, a representative signal of the current provided at the output by the reference voltage generator include means for measuring the instantaneous intensity consumed by the reference voltage generator.

8. The amplifier according to claim 1, characterized in that said means for inputting at the input of the power voltage generator, a representative signal of the current provided at the output by the reference voltage generator include means for measuring the current provided by the reference voltage generator, only positioned upstream from the output feeding the load and the output of the reference voltage generator is directly connected to the coupling point without interposition of any resistive element between them.

9. The amplifier according to claim 1, characterized in that the output impedance of the reference voltage generator is less than 0.2 Ohms.
